(19) United States
(12) Patent Application Publication
(10) Pub. No.: US 2012/0153461 A1
(43) Pub. Date: Jun. 21, 2012

(54) SEMICONDUCTOR COMPONENT, SEMICONDUCTOR WAFER COMPONENT, MANUFACTURING METHOD OF SEMICONDUCTOR COMPONENT, AND MANUFACTURING METHOD OF JOINING STRUCTURE

(75) Inventors: Hidetoshi Kitaura, Osaka (JP); Akio Furusawa, Osaka (JP); Shigeaki Sakatani, Osaka (JP); Taichi Nakamura, Osaka (JP); Takahiro Matsuo, Osaka (JP)

(73) Assignee: Panasonic Corporation, Osaka (JP)

(21) Appl. No.: 13/263,900

(22) PCT Filed: Jul. 20, 2010
(86) PCT No.: PCT/JP2010/004655

§ 371 Date: Oct. 11, 2011

(30) Foreign Application Priority Data
Jul. 24, 2009 (JP) 2009-172709

(51) Int. Cl. H01L 23/498; H01L 21/60

(52) U.S. Cl. 257/737; 438/113; 438/615; 257/E23.06; 257/E21.509; 257/E21.508

(57) ABSTRACT

A semiconductor component of the present invention includes a semiconductor element and a joining layer formed on one surface of the semiconductor element and consisting of a joining material containing Bi as an essential ingredient, and projecting sections are formed on a surface of the joining layer on a side opposite to a surface in contact with the semiconductor element. By joining the semiconductor component to an electrode arranged so as to face the joining layer, the generation of a void can be suppressed.

### CROSS-REFERENCE TO RELATED APPLICATIONS

This application is a U.S. national phase application of PCT International Patent Application No. PCT/JP2010/004655 filed Jul. 20, 2010, claiming the benefit of priority of Japanese Patent Application No. 2009-172709 filed Jul. 24, 2009, all of which are incorporated by reference herein in their entirety.

### TECHNICAL FIELD

The present invention relates to a semiconductor component having, on the surface of a semiconductor element, a joining layer made from a joining material containing Bi as an essential ingredient, a semiconductor wafer component, a manufacturing method of the semiconductor component, and a manufacturing method of a joining structure.

### BACKGROUND ART

A semiconductor component is mounted on a substrate using a soldering material. For example, as a soldering material used for joining a semiconductor component such as an IGBT (Insulated Gate Bipolar Transistor) to a substrate, a soldering material having a composition of Sn-3 wt % Ag-0.5 wt % Cu and having a melting point of 220° C. is generally used.

FIG. 4 is a schematic diagram showing a semiconductor component mounted on a substrate. When a semiconductor component 401 is mounted on a substrate 402, an external electrode 404 of the semiconductor component 401 is soldered to a substrate electrode 405 by a dipping device of a solder dipping type using, for example, a soldering material 403 having a composition of Sn-3 wt % Ag-0.5 wt % Cu and having a melting point of 220° C. At this time, the soldering material 403 is heated to 250 to 260° C. by the dipping device, and hence the temperature of the semiconductor component 401 may reach a temperature of 250 to 260° C. The semiconductor component 401 has a configuration in which a semiconductor element 406 is jointed to an internal electrode 407 by a joining material 408. However, when the joining material 408 is molten in the semiconductor component 401, a short circuit, a disconnection, or a change in the electrical characteristics may be caused, thereby resulting in a failure in a final product. Therefore, the joining material 408 used in the semiconductor component 401 is required to have a melting temperature higher than the highest temperature in the semiconductor component 401, which can be reached during the soldering step using the dipping device.

Thus, as a joining material having a melting temperature higher than 260° C. and containing no lead, a joining material containing 90 wt % or more of Bi (hereinafter referred to as a joining material containing Bi as an essential ingredient) (for example, a material having a composition of Bi-2.5 Ag and having a melting point of 262° C., and a material having a composition of Bi-0.5 Cu and having a melting point of 270° C.) is considered to be suitable. A material containing Zn has also been investigated as the other joining material, but at present, the joining material containing Bi as an essential ingredient is suitable in view of the wettability and the ease of joining. Thus, a power semiconductor module using the joining material containing Bi as an essential ingredient has been proposed (see Japanese Patent Laid-Open No. 2007-281412 (page 24, FIG. 2)).

FIG. 5(a) to FIG. 5(c) are schematic diagrams for explaining the generation of a void in the manufacturing process of the conventional joining structure described in Japanese Patent Laid-Open No. 2007-281412 (page 24, FIG. 2). In FIG. 5(a) to FIG. 5(c), a joining structure 501 is formed in such a manner that a molten joining material 502 containing Bi as an essential ingredient is supplied onto an electrode 503 (FIG. 5(a)) and that a semiconductor element 504 is then mounted on the joining material 502 (FIG. 5(b)) so as to be joined to the electrode 503 (FIG. 5(c)).

### CITATION LIST

### Patent Document

### SUMMARY OF INVENTION

### Technical Problem

However, Bi which is an essential ingredient of the joining material described in Japanese Patent Laid-Open No. 2007-281412 (page 24, FIG. 2) and whose standard formation energy of oxide is −494 kJ/mol is liable to be oxidized. As described above, in order to form the joining structure 501, the molten joining material 502 containing Bi as an essential ingredient is supplied onto the electrode 503, and the semiconductor element 504 is mounted on the joining material 502 so as to be joined to the electrode 503. In this case, on the surface of the molten joining material 502 containing Bi as an essential ingredient and supplied onto the electrode 503, an oxide 505, which is naturally generated by the exposure to the atmosphere, is formed.

For this reason, when the semiconductor element 504 is mounted on the surface of the molten joining material 502, the layer of the oxide 505 is wetly spread on the surface of the semiconductor element 504, and is eventually moved to the outer peripheral edge portion of the joining material 502. However, when air reservoirs exist as shown by the arrows in FIG. 5(b), there is a case where a part of the layer of the oxide 505 is left without being moved to the outer peripheral portion of the joining material 502. Further, the layer of the left oxide 505 has a characteristic to easily trap air, and hence the air reservoir surrounded by the layer of the oxide 505 is taken as a void 506 into the joining material 502. Note that the oxide 505 collected in the outer peripheral edge portion of the joining material 502 is distributed so as to substantially uniformly cover the surface of the outer peripheral edge portion of the joining material 502.

In the state where the void 506 is incorporated in the joining material 502, there is a problem that, when stress is repetitively applied to the solidified joining material 502 during the heat cycle, a crack is formed in the joining material 502, so that a failure of the semiconductor component having the joining structure 501 is caused.

The present invention has been made in view of the above-described problem of the conventional semiconductor component. The present invention is directed to a semiconductor component which can reduce the generation of a void in the joining layer consisting of the joining material containing Bi as an essential ingredient, a joining structure configured by joining the semiconductor component to an electrode, a semiconductor wafer component, a manufacturing method of the semiconductor component, and a manufacturing method of the joining structure.

### Means for Solving the Problems

The 1^{st} aspect of the present invention is a semiconductor component comprising:
a semiconductor element; and
a joining layer formed on one surface of the semiconductor element and consisting of a joining material containing Bi as an essential ingredient,
wherein one or more projecting sections are formed on a surface of the joining layer on a side opposite to a surface in contact with the semiconductor element.

The 2^{nd} aspect of the present invention is the semiconductor component according to the 1^{st} aspect of the present invention, wherein a height of the projecting section is 5 μm or more to 30 μm or less.

The 3^{rd} aspect of the present invention is a manufacturing method of a semiconductor component, comprising:
forming a joining layer with a joining material containing Bi as an essential ingredient on one surface of a semiconductor wafer with a plurality of semiconductor elements formed thereon;
arranging a mask on the joining layer, in which one or more hole sections are formed for each area corresponding to the position of each of the semiconductor elements;
forming one or more projecting sections with the same kind of material as the joining layer or a material having a melting start temperature lower than a melting start temperature of the joining material on the joining layer with the mask arranged thereon, the one or more projecting sections corresponding to the hole sections; and
cutting the semiconductor wafer with the projecting section formed on the joining layer.

The 4^{th} aspect of the present invention is the manufacturing method of the semiconductor component according to the 3^{rd} aspect of the present invention, wherein a thickness of the mask at the hole section corresponds to a height of the projecting section, and
wherein a size of an opening of the hole section of the mask on a surface in contact with the joining layer is wider than a size of an opening on the side opposite to the opening.

The 5^{th} aspect of the present invention is a manufacturing method of a joining structure formed by joining the semiconductor component according to the 1^{st} aspect of the present invention to an electrode, comprising:
arranging the semiconductor component so that the surface of the joining layer faces the electrode at a predetermined distance, the surface having the projecting section formed thereon;
heating the electrode to a melting start temperature or more of the joining material; and
moving the semiconductor component to a side of the heated electrode and bringing the projecting section into contact with a surface of the electrode, so that starting to melt the joining layer from the projecting section as a starting point.

The 6^{th} aspect of the present invention is a semiconductor wafer component comprising:
a semiconductor wafer on which a plurality of semiconductor elements are formed;
a joining layer which is formed on a surface of the semiconductor wafer with the semiconductor elements formed on the surface and consists of a joining material containing Bi as an essential ingredient; and
a protective sheet bonded on the joining layer,
wherein one or more projecting sections are formed on a surface of the joining layer on a side of the protective sheet and for each area corresponding to a position of each of the semiconductor elements.

The 7^{th} aspect of the present invention is a manufacturing method of a joining structure formed by joining the semiconductor component according to the 2^{nd} aspect of the present invention to an electrode, comprising:
arranging the semiconductor component so that the surface of the joining layer faces the electrode at a predetermined distance, the surface having the projecting section formed thereon;
heating the electrode to a melting start temperature or more of the joining material; and
moving the semiconductor component to a side of the heated electrode and bringing the projecting section into contact with a surface of the electrode, so that starting to melt the joining layer from the projecting section as a starting point.

An invention relating to the present invention is a joining structure comprising:
a semiconductor element;
a joining layer which is formed on one surface of the semiconductor element and consists of a joining material containing Bi as an essential ingredient; and
an electrode which is joined oppositely to the joining layer and has one or more projecting sections on the surface thereof on the side of the joining layer.

Further, another invention relating to the present invention is a manufacturing method of the joining structure of the above-described invention relating to the present invention, the manufacturing method comprising:
an arranging step of arranging the semiconductor component so that the joining layer faces the surface of the electrode at a predetermined distance, the surface having the projecting section formed thereon;
a heating step of heating the electrode to the melting temperature or more of the joining material; and
a joining step in which the semiconductor component is moved to the side of the heated electrode and the projecting section is brought into contact with the surface of the joining layer, so that the melting of the joining layer is started with the projecting section as a starting point.

In the structure according to the present invention, the joining layer consisting of the joining material containing Bi as an essential ingredient is provided on one surface of the semiconductor element, and the projecting section is formed, for example, on the surface of the joining layer on the side opposite to the surface in contact with the semiconductor element, whereby an air passage is occurred around the projecting section at the time of joining the joining layer to the electrode and thereby the generation of a void which is air surrounded by the oxide of Bi can be suppressed.

### Advantageous Effects of Invention

The present invention exhibits the effect of reducing the generation of a void in the joining layer consisting of the joining material containing Bi as an essential ingredient.

### BRIEF DESCRIPTION OF DRAWINGS

FIG. 1(a) to FIG. 1(e) are schematic diagrams of a semiconductor component according to embodiment 1 of the present invention.

FIG. 2(a) to FIG. 2(d) are diagrams showing a step of soldering the semiconductor component to a lead frame, according to embodiment 1 of the present invention.

FIG. 3 is a diagram showing a relationship of the void generation rate with respect to the height of the projecting section.

FIG. 4 is a schematic diagram showing a state in which a semiconductor component is mounted on a substrate.

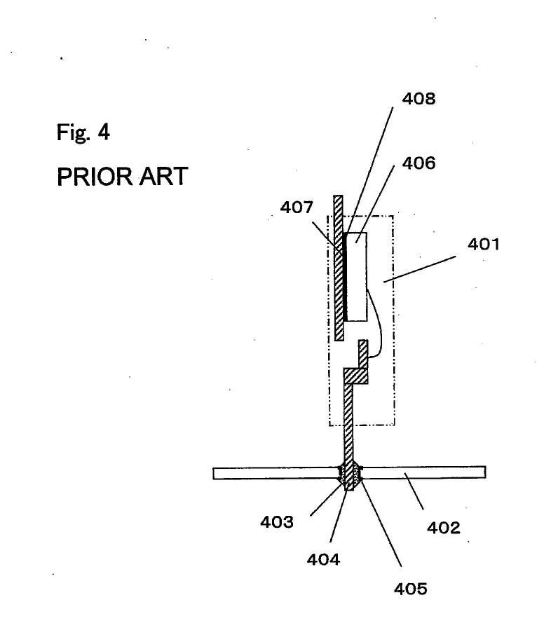

FIG. 5(a) to FIG. 5(c) are schematic diagrams for explaining the generation of a void in a manufacturing process of a conventional joining structure.

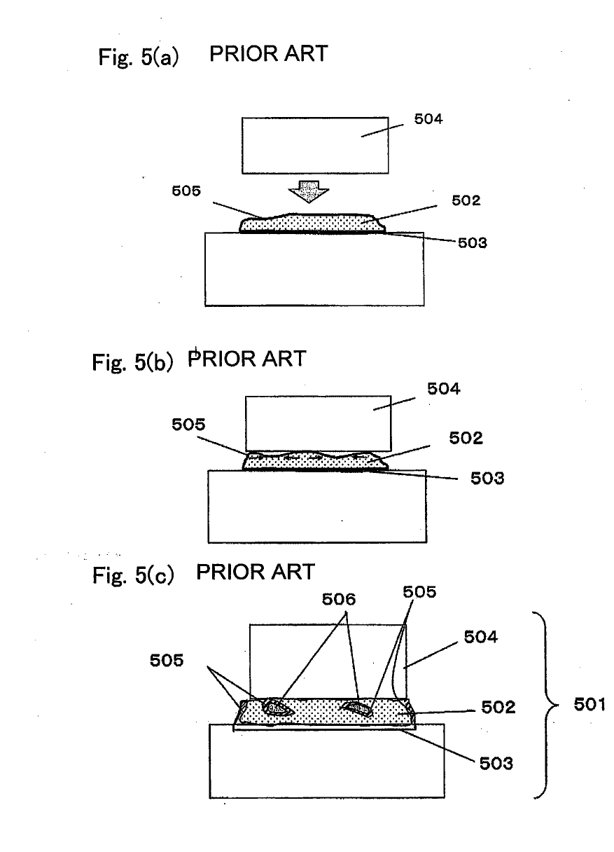

FIG. 6 is a schematic sectional view for explaining a mask used in a manufacturing method of the semiconductor component according to embodiment 1 of the present invention.

FIG. 7 is a schematic sectional view showing an electrode structure of a joining structure according to another embodiment of the present invention.

### DESCRIPTION OF EMBODIMENTS

In the following, embodiments according to the present invention will be described with reference to the accompanying drawings.

### Embodiment 1

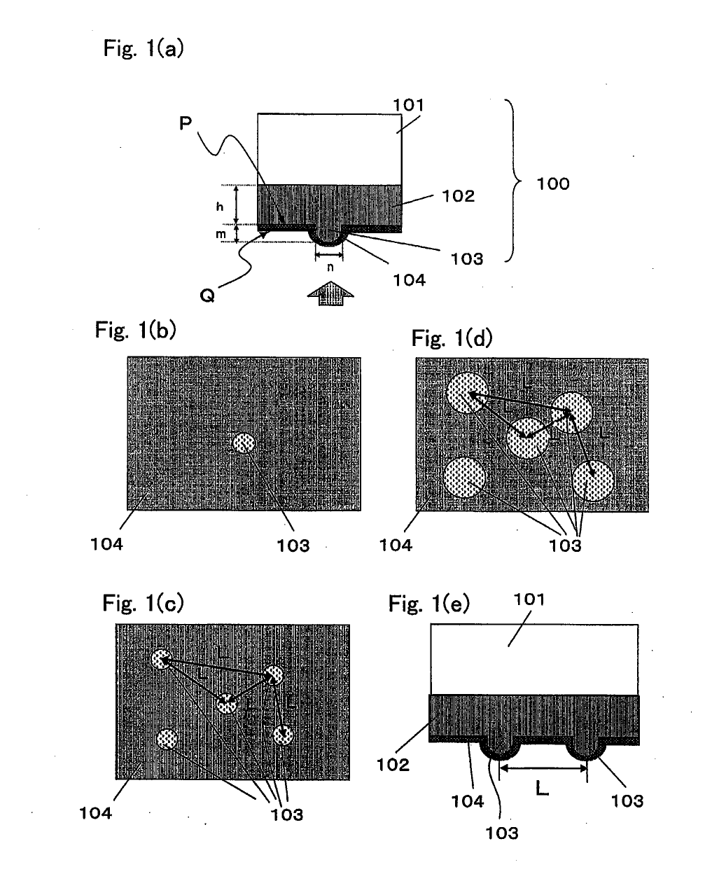

FIG. 1(a) to FIG. 1(e) are schematic diagrams of a semiconductor component according to embodiment 1 of the present invention. FIGS. 1(a) and (e) are sectional views of the semiconductor component, and FIGS. 1(b), (c) and (d) are plan views of the joining layer of the semiconductor component when viewed from the arrow direction in FIG. 1(a).

A semiconductor element 101 is made from Si, and is cut out in a size of 4.5 mm×3.55 mm from a wafer (semiconductor wafer) having a diameter of 6 inches and a thickness of 0.3 mm. The semiconductor element 101 may be made from not only Si but also Ge, and further, may also be made from a compound semiconductor, such as GaN, GaAs, InP, ZnS, ZnSe, SiC and SiGe. Further, as for the size of the semiconductor element 101, a semiconductor element having a large size of 6 mm×5 mm, or a semiconductor element 101 having a small size, such as 3 mm×2.5 mm and 2 mm×1.6 mm, may also be used according to the function of the semiconductor element 101. The thickness of the semiconductor element 101 is not limited to 0.3 mm, and a semiconductor element having a thickness, such as 1.0 mm, 0.5 mm, 0.1 mm and 0.01 mm, may also be used.

A joining layer 102 is made from Bi-2.5 wt % Ag (having a melting point of 262° C.), and one hemispherical projecting section 103 is formed in the central portion of the surface of the joining layer 102 on the side opposite to the side in contact with the semiconductor element 101. Further, an oxide 104, which is naturally generated by the exposure to the atmosphere, is formed on the surface of the joining layer 102 and of the projecting section 103 on the side opposite to the side of the semiconductor element 101.

The thermal conductivity of Bi which is the main component of the joining layer 102 is 9 W/m·K. Thus, when the thickness h of the joining layer 102 is too large, the product performance of the semiconductor component will not be satisfied from the view point of thermal resistance, and when the thickness h of the joining layer 102 is too small, joint failure is caused. From the above, it is preferred that the thickness h of the joining layer 102 is set to about 10 μm or more and about 30 μm or less.

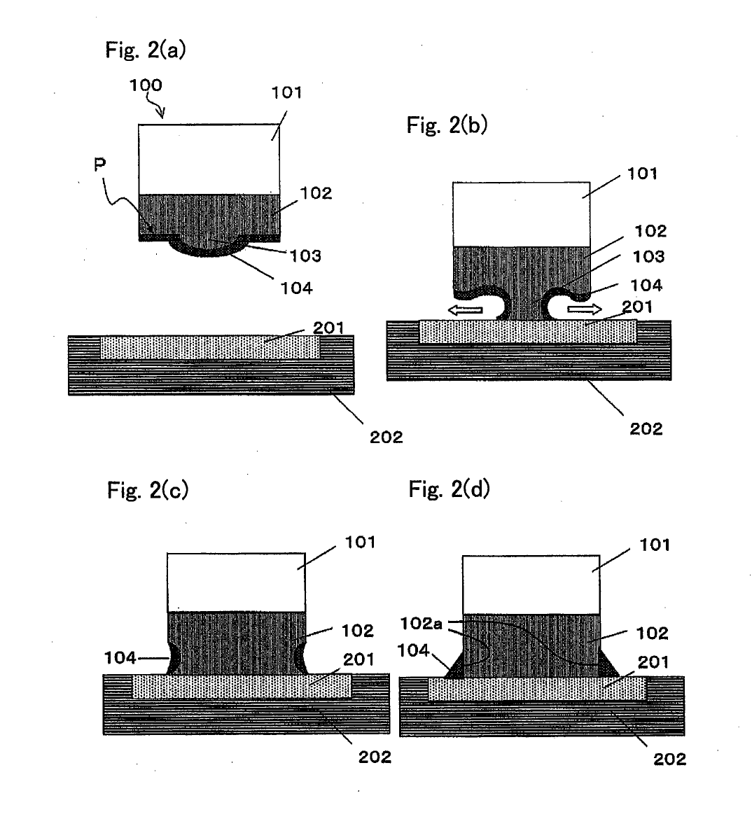

The size of the projecting section 103, which is formed in an approximately hemispherical shape, is set such that the maximum height m in the normal direction is 10 μm on the basis of the surface of the joining layer 102 on the side opposite to the side in contact with the semiconductor element 101 (plane P corresponding to the position indicated by reference character P in FIG. 1(a)), that is, on the basis of the plane P of the joining layer 102 on the side of an electrode 201 (see FIG. 2(a)) described below, and such that the maximum diameter n in the plane direction is 10 μm.

Here, when the projecting section 103 is formed and then exposed to the atmosphere, the layer of the oxide 104 is naturally generated, but the thickness of the layer of the oxide 104 is substantially uniform. Therefore, the height of the projecting section 103 after the formation of the layer of the oxide 104 will be described below under the assumption that the height based on the surface of the layer of the oxide 104 on the side of the electrode 201 (based on the plane Q corresponding to the position indicated by reference character Q in FIG. 1(a)) is equal to the height of the projecting section 103 before the formation of the oxide 103 (the height based on the plane P). Thus, in the following, unless specifically described otherwise, the height of the projecting section is assumed to be the maximum height in the normal direction based on the plane P.

Note that, since it is only necessary that a passage of the air existing between the joining layer 102 and the electrode 201 (see FIG. 2(b)) described below or a passage of the air trapped by the oxide 104 can be secured, the shape of the projecting section 103 may also be formed into a polygonal pyramid shape in the perpendicular direction with respect to the surface of the joining layer 102 on the side opposite to the side in contact with the semiconductor element 101.

Next, while a method for forming the projecting section 103 is described, an example of a manufacturing method of the semiconductor component according to the present invention will be described.

In a joining layer forming step, the joining layers 102 made from a joining material containing Bi as an essential ingredient are formed by electrolytic plating so as to have a desired thickness with respect to the main surface of a semiconductor wafer on which surface a plurality of semiconductor elements are formed.

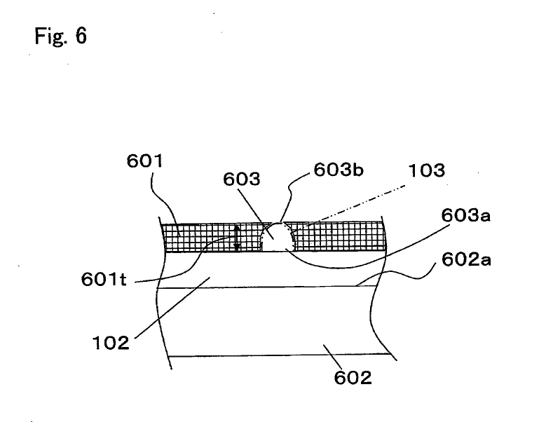

Then, as shown in FIG. 6, in a mask arranging step, a mask 601 having a plurality of hole sections each corresponding to the shape of the projecting section 103 is arranged on the formed joining layer 102.

Here, in the mask 601, one or more hole sections 603 are formed in each region corresponding to each position of the plurality of semiconductor elements formed on the main surface 602a of the semiconductor wafer 602. Further, as shown in FIG. 6, the thickness 601t of the mask 601 in the hole section 603 corresponds to the height of the projecting section 103. Further, the shape and size of an opening section 603a of the hole section 603, which is formed in the surface of the mask 601 on the side in contact with the joining layer 102, corresponds to the shape and size of the root of the projecting section 103, while the shape and size of an opening section 603b of the same hole section 603, which is formed in the surface of the mask 601 on the side facing oppositely to the opening section 603a, corresponds to the shape and size of the tip section of the projecting section 103.

Next, after the mask 601 is arranged in the mask arranging step, the joining material containing Bi as an essential ingredient is formed into the shape of the projecting section 103 by electrolytic plating. When the mask 601 is removed after the electrolytic plating, the projecting section 103 is formed on the surface of the joining layer 102 on the side opposite to the side in contact with the semiconductor element 101.

Note that the height of the projecting section 103 can be adjusted by controlling the time during which the semiconductor wafer 602 with mask 601 arranged thereon is subjected to the electrolytic plating.

Next, a dicing sheet serving as a protective sheet is bonded on the side of the main surface 602a of the semiconductor wafer 602 on which side the projecting section 103 is formed. Then, in a cutting step, the semiconductor wafer 602 is cut in a predetermined size by a dicing device. The semiconductor wafer 602, to which the dicing sheet is bonded, is an example of a semiconductor wafer component according to the present invention.

FIG. 1(b) is a plan view showing the surface of the joining layer on the side opposite to the surface in contact with the semiconductor element. Since the projecting section 103 is formed at one place, an air passage is occurred around the projecting section 103 at the time of joining to the electrode, so that the generation of a void which is the air surrounded by the oxide of Bi can be prevented.

FIG. 1(c) is a plan view which shows the surface of the joining layer 102 on the side opposite to the surface in contact with the semiconductor element 101, and which shows a state where five projecting sections 103 are formed on the plane of the oxide 104. The distance L, shown in FIG. 1(c), between the projecting section 103 and another projecting section 103 adjacent to the projecting section 103 is, as shown in FIG. 1(e), the distance between the vertexes of the projecting sections 103 based on the surface (the surface of the oxide 104) of the joining layer 102 on the side opposite to the surface in contact with the semiconductor element 101. In the case of FIG. 1(c), when attention is directed to the distance L between the projecting sections 103 adjacent to each other, the projecting sections 103 are arranged so that the distance L is set longer for the projecting section 103 located closer to the outer periphery of the oxide 104.

FIG. 1(d) shows the state of wet-spreading of the joining layer at the time when the joining layer is molten from the projecting sections 103 shown in FIG. 1(c). As described above, the distance L is set longer for the projecting section 103 located closer to the outer periphery of the oxide 104, and hence the molten portion with the projecting section 103 as a starting point is wetly spread to the outer peripheral portion of the oxide 104 at the time of joining to the electrode 201. Thus, since the outer periphery of the molten portion with the projecting section 103 as a starting point serves as an air passage, the passage of the air surrounded by the oxide of Bi is prevented from being closed, and hence the generation of a void is prevented.

FIG. 2 is a diagram showing a step of soldering the semiconductor component according to embodiment 1 of the present invention to a lead frame. Each diagram in FIG. 2 shows a cross section.

In the following, an example of a manufacturing method of the joining structure according to the present invention will be described with reference to FIG. 2.

FIG. 2(a) shows an arranging step in which a semiconductor component 100 is arranged in the vicinity of the electrode 201 of a lead frame 202. That is, in this step, the semiconductor component 100 is held by a holding device (not shown) so that the surface of the joining layer 102 with the projecting section 103 formed thereon faces the electrode 201 at a predetermined distance.

Further, as shown in FIG. 2(a), the substantially hemispherical projecting section 103 is formed at a central portion of the surface of the joining layer 102 on the side of the electrode 201. On the surface of the joining layer 102 on the side of the electrode 201, the oxide 104, which is naturally generated when the joining layer 102 is exposed to the atmosphere, is formed. FIG. 2(a) shows a state before the semiconductor component 100 is joined to the electrode 201 of the lead frame 202.

FIG. 2(b) is a schematic diagram showing a state where the semiconductor component 100 is held above the electrode 201 by the holding device when the lead frame 202 is heated to at least the temperature of 262° C. which is the melting start temperature of the joining layer 102.

When the joining layer 102 is to be joined to the electrode 201 as shown in FIG. 2(b), the oxide 104 of the projecting section 103 is first brought into contact with the electrode 201, so that heat is conducted from the electrode 201 to the joining layer 102 through the oxide 104 and the projecting section 103. Thereby, the projecting section 103 is first molten, and then, the joining layer 102 in contact with the projecting section 103 is molten, so that, while the molten area is spread toward the peripheral portion of the joining layer 102, the joining of the electrode 201 and the joining layer 102 is completed. Note that the holding device holds the semiconductor component 100 and also moves the semiconductor component 100 gradually downward in accordance with the spread state of the molten area.

In this way, the time difference is provided in the timing of melting of the joining layer 102, and thereby the oxide 104 is pushed out to the outer peripheral edge portion of the joining layer 102 as shown in FIG. 2(c).

FIG. 2(d) is a schematic diagram showing the joining structure in which the semiconductor component and the lead frame are joined to each other. As shown in FIG. 2(d), the oxide 104 is pushed out to the outer peripheral edge portion of the joining layer 102 so as to be moved to the outer peripheral surface 102a of the joining layer on the side of the electrode 201, and hence the oxide 104 does not exist in the joining layer 102. Therefore, the void generation due to the trapping of air by the oxide 104 is prevented.

Therefore, the present embodiment has the feature that the oxide, which exists on the outer peripheral edge portion of the joining layer 102, is distributed more on the outer peripheral edge portion (portion corresponding to the outer peripheral surface 102a) on the side of the electrode 201 as compared with the outer peripheral edge portion on the side of the semiconductor element 101.

With this configuration, when an electrode is joined to a semiconductor component which includes a semiconductor element, and a joining layer made from a joining material containing Bi as an essential ingredient and provided on one surface of the semiconductor element, and in which a projecting section is formed on the surface of the joining layer on the side opposite to the surface in contact with the semiconductor element, the peripheral area of the projecting section serves as an air passage, so that the generation of a void which is the air surrounded by the oxide of Bi can be suppressed or prevented.

### Embodiment 2

In the semiconductor component according to embodiment 1, the projecting section 103 is formed on the surface of the joining layer on the side opposite to the surface in contact with the semiconductor element, and is formed in a hemispherical shape whose maximum height m in the normal direction is 10 μm on the basis of the plane P (see FIG. 1(a)), and whose maximum diameter n in the plane direction is 10 μm.

However, it is also conceivable that, when the height of the projecting section is set extremely low, the air passage is easily closed. Thus, the relationship between the height of the projecting section and the presence/absence of generation of the void was verified.

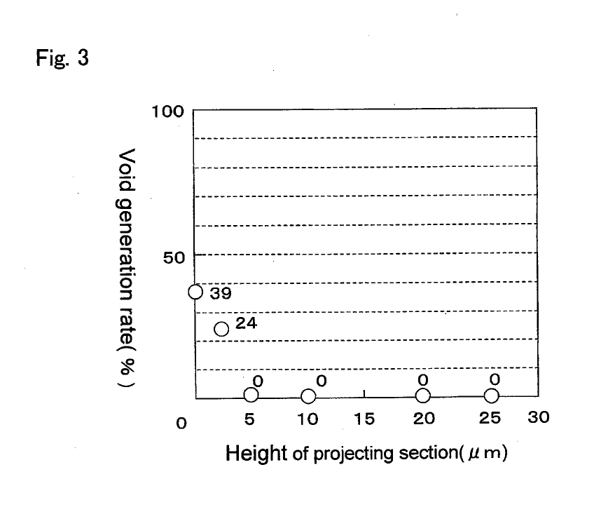

FIG. 3 is a diagram showing a relationship of the void generation rate with respect to the height of the projecting section. In the experiment at this time, one projecting section was provided at the central portion of the joining layer.

The void generation rate (%) is expressed as follows:

Void generation rate (%)=(void area)÷surface area of joining material×(100) (%)

The void area in an IGBT, in which the semiconductor component was joined and assembled, was measured by a transmission X-ray apparatus.

As can be seen from the results of FIG. 3, in the case where the height of the projecting section is set to 5 μm, the void generation rate is 0%, and hence the effect of preventing the generation of a void is sufficiently obtained by providing the projecting section. On the other hand, in the case where the height of the projecting section is set to 3 μm, the void generation rate is 24%, and hence the generation of a void cannot be prevented. In this case, the projecting section is molten and then the joining layer is molten and joined to the electrode. However, since the height of the projecting section is insufficient, the joining layer is molten and joined to the electrode before the void is pushed out. Thereby, the passage of the void is closed, so that the void is left in the solder. Further, in the case where the height of the projecting section was set to 4 μm, a slight void was left in the solder.

On the other hand, in the case where the height of the projecting section is set to 25 μm, the void generation rate is also 0%, but the case where the height of the projecting section is set higher than this value will be described.

For example, in the case where the height of the projecting section was set to 30 μm, the void generation rate was 0%. However, when the height of the projecting section exceeds 30 μm, and when the semiconductor wafer is bonded to a dicing sheet so as to be cut by a dicing device in the cutting step as described above, the projecting section 103 causes an air bubble to be generated between the dicing sheet and the bonding surface of the joining layer 102 bonded to the dicing sheet. When dicing is performed in this state, cutting chips generated during the dicing is trapped in the air bubble and contaminates the surface of the joining layer, so that a junction failure is caused. Thus, it is not preferred that the height of the projecting section is set to exceed 30 μm. From the above results, it is preferred that the height of the projecting section is set to 5 μm or more to 30 μm or less.

In the above-described verification, a semiconductor component using the joining material having the composition of Bi-2.5 wt % Ag was used, but the effectiveness of the projecting section was also verified by using a joining material having another composition.

Table 1 shows the results of the measurement of void generation rate performed by changing the kind of the joining layer, the height of the projecting section, and the number of the projecting sections. Also when no projecting section was formed, the verification was performed for reference (comparison example 1).

TABLE 1

| | | Height of | Number of | Void |
|---|---|---|---|---|
| | | projecting | projecting | generation |
| | Joining layer | section | sections | rate |
| Example 1 | Bi—2.5 Wt % Ag | 5 μm | 1 | ⊚0% |
| Example 2 | Bi—2.5 Wt % Ag | 10 μm | 1 | ⊚0% |
| Example 3 | Bi—2.5 Wt % Ag | 20 μm | 1 | ⊚0% |
| Example 4 | Bi—2.5 Wt % Ag | 25 μm | 1 | ⊚0% |
| Example 5 | Bi—0.8 Wt % Cu | 5 μm | 1 | ⊚0% |
| Example 6 | Bi—0.8 Wt % Cu | 10 μm | 1 | ⊚0% |
| Example 7 | Bi—0.8 Wt % Cu | 25 μm | 1 | ⊚0% |
| Example 8 | Bi—0.8 Wt % Cu | 5 μm | 3 | ⊚0% |
| Example 9 | Bi—0.8 Wt % Cu | 5 μm | 10 | ⊚0% |
| Example | Bi—1.0 Wt % | 5 μm | 1 | ⊚0% |
| 10 | Ag—0.5 Wt % Cu | | | |
| Example | Bi—1.0 Wt % | 10 μm | 1 | ⊚0% |
| 11 | Ag—0.5 Wt % Cu | | | |
| Example | Bi—1.0 Wt % | 25 μm | 1 | ⊚0% |
| 12 | Ag—0.5 Wt % Cu | | | |
| Example | Bi—1.0 Wt % | 25 μm | 3 | ⊚0% |
| 13 | Ag—0.5 Wt % Cu | | | |
| Example | Bi—1.0 Wt % | 25 μm | 5 | ⊚0% |
| 14 | Ag—0.5 Wt % Cu | | | |
| Example | Bi—1.0 Wt % | 25 μm | 10 | ⊚0% |
| 15 | Ag—0.5 Wt % Cu | | | |
| Example | Bi | 5 μm | 1 | ⊚0% |
| 16 | | | | |
| Comparison | Bi—2.5 Wt % Ag | 0 μm | 0 | X39% |
| example 1 | | | | |
| Comparison | Bi—2.5 Wt % Ag | 3 μm | 1 | X24% |
| example 2 | | | | |

As can be seen from table 1, also when Bi-1.0 wt % Ag-0.5 wt % Cu was used as the joining material, and 100 wt % Bi was used as the joining material, the void generation rate was 0%. It was seen from these results that, when a material containing Bi as an essential ingredient was used as the joining material, the generation of a void could be prevented. When the height of the projecting section was set to 5 μm or more to 30 μm or less, the void generation rate was 0%. Further, when the above-described arrangement conditions of the projecting sections were satisfied, the void generation rate was 0% without being influenced by the number of the projecting sections. Further, in comparison example 1 with no projecting section, the void generation rate was 39%, and hence, it is hard to say that the quality of comparison example 1 is stable.

With this configuration, when an electrode is joined to a semiconductor component which includes a semiconductor element, and a joining layer made from a joining material containing Bi as an essential ingredient and provided on one surface of the semiconductor element, and in which a projecting section having a height of 5 μm or more to 30 μm or less is formed on the surface of the joining layer on the side opposite to the surface in contact with the semiconductor element, an air passage is occurred around the projecting section and thereby the generation of a void which is the air surrounded by the oxide of Bi can be prevented.

Since an air passage occurs around the projecting section and thereby the generation of a void which is the air surrounded by the oxide of Bi is prevented, it is also conceivable that the size of the projecting section for preventing the generation of a void relates to the volume of the projecting section. This is because, when a fixed volume of space is maintained around the projecting section, the space serves as an air passage.

Further, in the above-described embodiment, a case where the number of the projecting section 103 is one is mainly described. However, the embodiment according to the present invention is not limited to this, and a plurality of projecting sections 103 may also be provided. Particularly, in the case where three or more projecting sections 103 are formed so as to support the semiconductor element 101, it is possible to prevent the semiconductor component 100 from inclining at the time when the semiconductor component 100 is mounted on the electrode.

Further, in the above-described embodiment, a case where the material of the projecting section 103 has the same composition as the material of the joining layer 102 is described. However, the embodiment according to the present invention is not limited to this, and a material whose composition is different from the composition of the material of the joining layer 102 and whose melting point is the melting start temperature or lower of the material of the joining layer 102 may also be used as the material of the projecting section 103. For example, a material, such as a Bi—Sn alloy (melting start temperature: 139° C.), a Sn—In alloy (melting start temperature: 120° C.), or a Bi—In alloy (melting start temperature: 73° C.), can be used as the material of the projecting section 103. Thereby, the melting can be surely started from the projecting section 103.

Further, in the above-described embodiment, a case where the projecting section 103 is formed in a part of the surface of the joining layer 102 is described. However, the embodiment according to the present invention is not limited to this, and for example, the whole surface of the joining layer 102 on the side of the electrode 201 may also be formed into a pyramid shape, such as a quadrangular pyramid shape, and a conical shape, which has the vertex thereof in the center of the surface. Even in this case, the same effect as that described above can be exhibited because the surface of the joining layer 102 on the side of the electrode 201 is inclined toward the outer peripheral side whereby the time difference is generated in the melting timing and also the air passage for releasing the air is secured.

Further, in the above-described embodiment, a configuration is described in which, while the semiconductor component 100 is held by the holding device, the semiconductor component 100 is moved gradually downward in accordance with the spreading state of the molten area. However, the embodiment according to the present invention is not limited to this, and for example, a configuration may also be used in which the semiconductor component 100 is mounted on the electrode 201 by the holding device and then the semiconductor component 100 is released from the holding device. In this case, the semiconductor component 100 is moved gradually downward by its own weight.

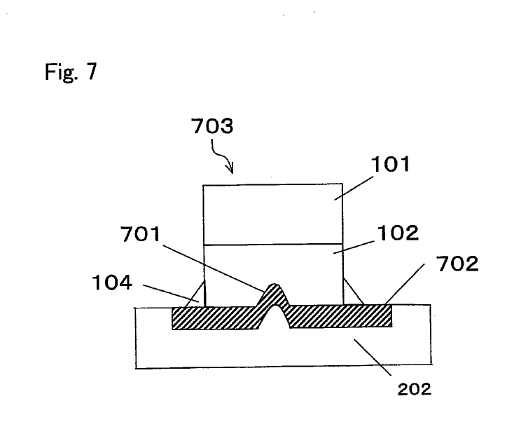

Further, in the above-described embodiment, a case where the projecting section is provided on the surface of the joining layer is described. However, the embodiment according to the present invention is not limited to this, and for example, a configuration in which one or more projecting sections are provided on the surface of the electrode may also be used. In this case, the projecting section on the electrode can be easily formed by pressing the electrode with a press die. FIG. 7 is a schematic cross-sectional view showing a joining structure 703 comprising a semiconductor element 101, a joining layer 102 formed on one surface of the semiconductor element 101 and consisting of a material containing Bi as an essential ingredient, an electrode 702 joined oppositely to the joining layer 102 and having a projecting section 701 at the center of the surface thereof on the side of the joining layer 102, and the lead frame 202. The same portions as those in FIG. 2(d) are denoted by the same reference numerals. That is, in the case of the configuration shown in FIG. 7, the projecting section 103 described with reference to FIG. 2(a) is not formed on the joining layer 102, but instead of the projecting section 103, the projecting section 701 is formed on the side of the electrode 702.

Further, a manufacturing method of the joining structure 703 shown in FIG. 7 is configured to comprise: an arranging step of arranging the semiconductor component 100 so that the joining layer 102 faces the surface of the electrode 702 at a predetermined distance, the surface having the projecting section 701 formed thereon; a heating step of heating the electrode 702 to the melting temperature or more of the joining material of the joining layer, the joining material containing Bi as an essential ingredient; and a joining step in which the semiconductor component 100 is moved to the side of the heated electrode and the projecting section 701 is brought into contact with the surface of the joining layer 102 with an oxide naturally formed thereon, so that the melting of the joining layer 102 is started with the projecting section 701 as a starting point. The manufacturing method of the joining structure 703 is fundamentally the same as the manufacturing method of the joining structure described with reference to FIG. 2. Therefore, even in this case, similarly to the above-described manufacturing method, the same effect as that described above can be exhibited because the time difference is generated in the melting timing of the oxide on the joining layer 102 and also the air passage for releasing the air is secured.

### INDUSTRIAL APPLICABILITY

The semiconductor component, the joining structure, the semiconductor wafer component, the manufacturing method of the semiconductor component, and the manufacturing method of the joining structure, according to the present invention, can reduce the generation of a void in the joining layer consisting of the joining material containing Bi as an essential ingredient, and hence can be applied for use in semiconductor packages of a power semiconductor, a small power transistor, and the like.

### REFERENCE SIGNS LIST

100 Semiconductor component
101 Semiconductor element
102 Joining layer
103 Projecting section
104 Oxide
201 Electrode
202 Lead frame

1. A semiconductor component comprising:
a semiconductor element; and
a joining layer formed on one surface of the semiconductor element and consisting of a joining material containing Bi as an essential ingredient,
wherein one or more projecting sections are formed on a surface of the joining layer on a side opposite to a surface in contact with the semiconductor element.

2. The semiconductor component according to claim 1, wherein a height of the projecting section is 5 μm or more to 30 μm or less.

3. A manufacturing method of a semiconductor component, comprising:
forming a joining layer with a joining material containing Bi as an essential ingredient on one surface of a semiconductor wafer with a plurality of semiconductor elements formed thereon;
arranging a mask on the joining layer, in which one or more hole sections are formed for each area corresponding to the position of each of the semiconductor elements;
forming one or more projecting sections with the same kind of material as the joining layer or a material having a melting start temperature lower than a melting start temperature of the joining material on the joining layer with the mask arranged thereon, the one or more projecting sections corresponding to the hole sections; and
cutting the semiconductor wafer with the projecting section formed on the joining layer.

4. The manufacturing method of the semiconductor component according to claim 3, wherein a thickness of the mask at the hole section corresponds to a height of the projecting section, and
wherein a size of an opening of the hole section of the mask on a surface in contact with the joining layer is wider than a size of an opening on the side opposite to the opening.

5. A manufacturing method of a joining structure formed by joining the semiconductor component according to claim 1 to an electrode, comprising:
arranging the semiconductor component so that the surface of the joining layer faces the electrode at a predetermined distance, the surface having the projecting section formed thereon;
heating the electrode to a melting start temperature or more of the joining material; and
moving the semiconductor component to a side of the heated electrode and bringing the projecting section into contact with a surface of the electrode, so that starting to melt the joining layer from the projecting section as a starting point.

6. A semiconductor wafer component comprising:
a semiconductor wafer on which a plurality of semiconductor elements are formed;
a joining layer which is formed on a surface of the semiconductor wafer with the semiconductor elements formed on the surface and consists of a joining material containing Bi as an essential ingredient; and
a protective sheet bonded on the joining layer,
wherein one or more projecting sections are formed on a surface of the joining layer on a side of the protective sheet and for each area corresponding to a position of each of the semiconductor elements.

7. A manufacturing method of a joining structure formed by joining the semiconductor component according to claim 2 to an electrode, comprising:
arranging the semiconductor component so that the surface of the joining layer faces the electrode at a predetermined distance, the surface having the projecting section formed thereon;
heating the electrode to a melting start temperature or more of the joining material; and
moving the semiconductor component to a side of the heated electrode and bringing the projecting section into contact with a surface of the electrode, so that starting to melt the joining layer from the projecting section as a starting point.
